(19) United States
(12) Patent Application Publication
(10) Pub. No.: US 2021/0309035 A1
(43) Pub. Date: Oct. 7, 2021

(54) DEVICE AND METHOD FOR PATTERN FORMING USING INKJET PRINTING

(71) Applicant: Bong Woo LEE, Asan-si (KR)

(72) Inventor: Bong Woo LEE, Asan-si (KR)

(21) Appl. No.: 17/172,091

(22) Filed: Feb. 10, 2021

(30) Foreign Application Priority Data
Apr. 4, 2020 (KR) 10-2020-0042734

(51) Int. Cl. B41M 3/00; B41M 7/00; B41J 11/00

(52) U.S. Cl. CPC B41M 3/003; B41M 7/009; G02B 5/223; B41J 11/0024; B41J 11/0022

(57) ABSTRACT

A device and method for pattern forming using inkjet printing are disclosed. A method for pattern forming using inkjet printing according to an aspect of the invention may include: forming a pattern by ejecting a solution by inkjet printing; and obtaining a degree of flatness by applying a pressure greater than or equal to atmospheric pressure simultaneously with a heat treatment on the pattern, where the cross section of the pattern is formed with a convex surface by the inkjet printing and is flattened by the applying of pressure, as the same force is applied perpendicularly on each surface of the pattern.

### CROSS-REFERENCE TO RELATED PATENT APPLICATION

This application claims the benefit of Korean Patent Application No. 10-2020-0042734, filed on Apr. 4, 2020, in the Korean Intellectual Property Office, the disclosure of which is incorporated herein in its entirety by reference.

### BACKGROUND

### 1. Technical Field

The present invention relates to a device and method for pattern forming using inkjet printing, more particularly to a pattern forming device and method that can flatten the surface of the ejected solution.

### 2. Description of the Related Art

Recent trends in the manufacture of color filters for organic light-emitting diode (OLED) and liquid crystal display (LCD) devices include ongoing research on forming patterns by inkjet printing using various materials such as RGB (red, green, blue), yellow, white, and transparent dyes and pigments. This is because, with photoresist processes using masks, materials discharged onto regions outside the intended patterns are discarded, leading to an increase in material costs.

With inkjet printing, however, there is difficulty in flattening out, to the required degree, the inkjet materials in the form of RGB or various other solutions enclosed within partition walls. Also, whereas a photoresist process can form a pattern that is already flattened, such flattening can be very difficult with inkjet printing, since the small amounts, i.e. one or two drops, of the solution discharged in-between partition walls are subject to various forces, such as the cohesion, adhesion, viscosity, etc., of the solution as well as the surface tension of the material itself. Also, in addition to surface tension, the state of surface treatment of the partition walls or portions touching the solution, the composition ratio of the solvent within the solution, or the form of solute may also have a large impact.

Depending on the type of solution used for the inkjet printing and the properties, form, etc., of the substance touching the solution, the cross section of the solution can have various shapes, as illustrated in FIGS. 1A through 10. Here, the most ideal shape is a flat shape such as that shown in drawing (a), and most inkjet solutions have a convex shape such as that shown in drawing (b). In some cases, an ejected inkjet solution can also have a concave shape such as that shown in drawing (c).

A solution ejected to the inside of partition walls by inkjet printing is heat treated for removing unnecessary solvent and drying, thus undergoing a procedure for solidifying into a pattern within the partition walls. If the substance remaining after the solvent is removed via heat treatment is level, this would be satisfactory. However, depending on the properties of the solution, the treatment condition of the partition walls, and the heat treatment conditions, the surface oftentimes is not level or flat, as in the examples illustrated in FIGS. 2B, 2C and 2D. If the surface of a pattern is not flat, then the thickness may be different at each position, which in turn can be expressed as defects in display quality due to differences in color reproduction and transmittance.

### SUMMARY OF THE INVENTION

An aspect of the invention, which has been derived to resolve the problem described above, is to provide a device and method for pattern forming that can flatten a solution ejected by inkjet printing.

Other objectives of the invention will be more clearly understood from the embodiments of the invention disclosed below.

A method for pattern forming using inkjet printing according to an aspect of the invention may include: forming a pattern by ejecting a solution by inkjet printing; and obtaining a degree of flatness by applying a pressure greater than or equal to atmospheric pressure simultaneously with a heat treatment on the pattern, where the cross section of the pattern is formed with a convex surface by the inkjet printing and is flattened by the applying of pressure, as the same force is applied perpendicularly on each surface of the pattern.

A pattern forming method using inkjet printing based on the present invention can include one or more of the following embodiments. For example, an operation of forming partition walls on one side of a substrate can further be included, where the solution can be ejected to the inside of the partition walls. The pattern can be a color filter for a display.

The heat treatment can be performed by at least one of a hot plate, a lamp, and a hot air blower and can be performed to dry and harden the ejected solution.

A pattern forming device using inkjet printing according to an aspect of the invention may include: a chamber having a sealed interior space; a heat treatment unit configured to apply heat treatment to a substrate positioned in the interior space; and a pressurization unit configured to flatten a pattern formed on the substrate by applying a pressure greater than or equal to atmospheric pressure in the interior space.

The heat treatment unit can include at least one of a hot plate, a lamp, and a hot air blower.

With the problem-solving means of the invention described above, one can expect various advantageous effects, including the following effects. However, this does not necessarily mean that the invention must exhibit all of the effects below.

An embodiment of the invention can provide a pattern forming device and method capable of flattening a solution ejected by inkjet printing.

Additional aspects and advantages of the present invention will be set forth in part in the description which follows, and in part will be obvious from the description, or may be learned by practice of the invention.

### BRIEF DESCRIPTION OF THE DRAWINGS

FIGS. 1A to 1C illustrate possible cross sections obtained after ejecting a solution to the inside of partition walls by using inkjet printing.

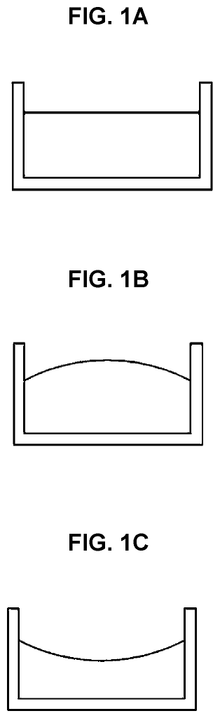

FIGS. 2A to 2D illustrate possible cross sections obtained after ejecting a solution to the inside of partition walls by using inkjet printing and applying heat treatment.

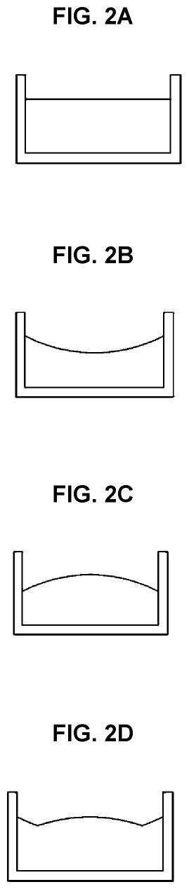

FIG. 3 is a flow diagram illustrating a method for pattern forming according to an embodiment of the invention.

FIG. 4 is a cross-sectional view illustrating a pattern formed by a solution ejected to the inside of partition walls by inkjet printing.

FIG. 5 is a cross-sectional view illustrating a solution subjected to pressure after being ejected to the inside of partition walls by inkjet printing.

FIG. 6 is a cross-sectional view illustrating the solution ejected to the inside of partition walls after being flattened by the pressure.

FIG. 7 is a diagram illustrating a pattern forming device according to a first disclosed embodiment of the invention.

FIG. 8 is a diagram illustrating a pattern forming device according to a second disclosed embodiment of the invention.

FIG. 9 is a diagram illustrating a pattern forming device according to a third disclosed embodiment of the invention.

FIG. 10 is a cross-sectional view illustrating a method of evening out the surface with inkjet printing after forming metal wiring.

### DETAILED DESCRIPTION OF THE INVENTION

As the invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed by the present invention. In the description of the present invention, certain detailed explanations of the related art are omitted if it is deemed that they may unnecessarily obscure the essence of the invention.

The terms used in the present specification are merely used to describe particular embodiments, and are not intended to limit the present invention. An expression used in the singular encompasses the expression of the plural, unless it has a clearly different meaning in the context. In the present specification, it is to be understood that the terms such as “including” or “having,” etc., are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

While such terms as “first” and “second,” etc., may be used to describe various components, such components must not be limited to the above terms. The above terms are used only to distinguish one component from another.

Certain embodiments of the present invention will be described below in more detail with reference to the accompanying drawings. Those components that are the same or are in correspondence are rendered the same reference numeral, and redundant descriptions are omitted.

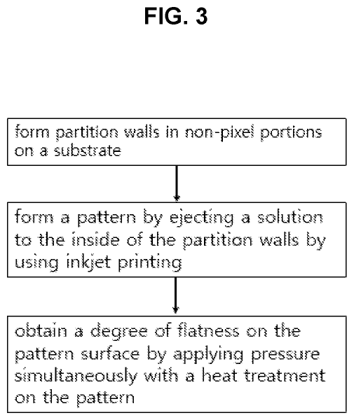

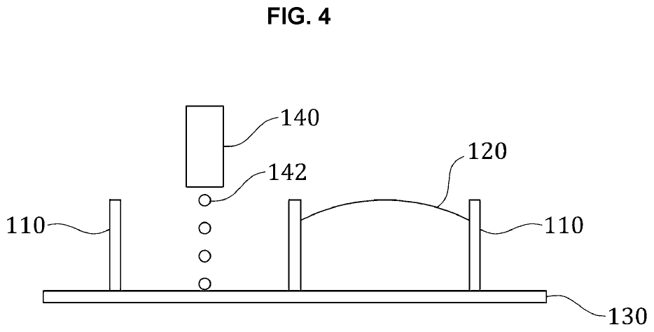

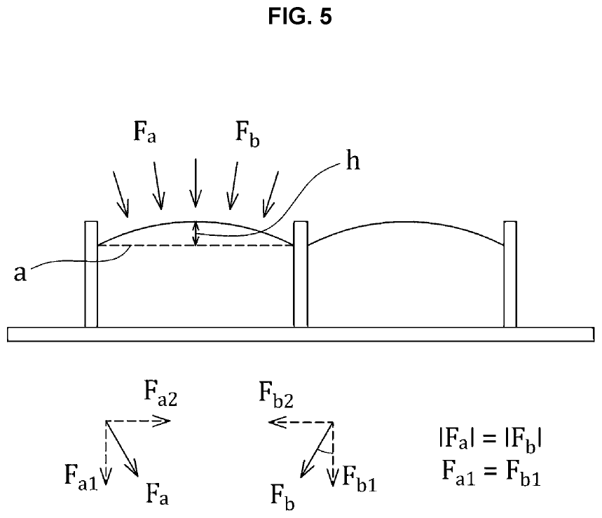

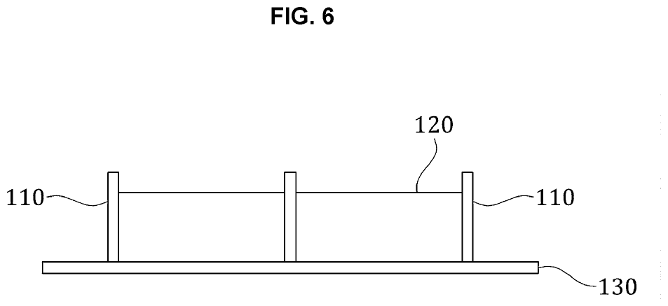

FIG. 3 is a flow diagram illustrating a method for pattern forming according to an embodiment of the invention, and FIG. 4 is a cross-sectional view illustrating a pattern 120 formed by a solution 142 ejected to the inside of partition walls 110 by an inkjet nozzle 140. FIG. 5 is a cross-sectional view illustrating the pattern 120 formed on the inside of the partition walls 110 being subjected to pressure. FIG. 6 is a cross-sectional view illustrating the pattern 120 after being flattened by the pressure.

Referring to FIGS. 3 to 6, a method for pattern forming according to an embodiment of the invention may include: forming partition walls 110 in non-pixel portions on a substrate 130, forming a pattern 120 by ejecting a solution 142 to the inside of the partition walls 110 by using an inkjet device 140, and obtaining a degree of flatness on the surface of the pattern 120 by applying pressure simultaneously with a heat treatment on the pattern 120.

First, partition walls 110 for forming pixels may be formed in non-pixel portions on the substrate 130. For the substrate 130, a known transparent substrate can be used, such as a glass substrate, a quartz substrate, a plastic substrate, etc. Among these substrate types, the glass substrate may provide advantages in terms of transparency, strength, and weather resistance.

The partition walls 110 can be formed in non-pixel portions, etc., on the substrate 130 for increased contrast. Also, the partition walls 110 can be formed by a black mattress, etc., and can be formed according to a known method. Some examples may include the method of forming a thin film of a metal or a metal oxide on a substrate and patterning the thin film by etching, etc., the method of applying a mixture of a coloring agent such as a pigment or dye, etc., and a photosensitive resin composition onto a substrate and applying photolithography, the method of dissolving a black pigment and a thermosetting resin in a solvent and printing the solution, and others.

An ink repellent for preventing color mixing of the solution can be coated on the partition walls 110. Color mixing can occur when a color ink is invaded by the color ink of an adjacent pixel. For the ink repellent, a silicon-based, fluorine-based material can be used.

After the partition walls 110 are formed, a solution 142 such as a color ink of RGB, yellow, white, and transparent dyes and pigments for the color filter of a display, for example, may be injected to the inside of the partition walls 110 by a inkjet printing method. The thermosetting resin used in the color ink can be selected from known materials used for the manufacture of a color filter substrate in consideration of the relationship with the coloring. Specifically, casein, gelatin, polyvinyl alcohol, carboxymethyl acetal, polyimide resin, acrylic resin, epoxy resin, etc., can be used. In particular, in cases for manufacturing a color filter where heat resistance or lightfastness is needed, acrylic resin can be used.

An inkjet device 140 for injecting a solution such as a color ink to the inside of the partition walls 110 can be of a piezo-conversion type or a thermal conversion type depending on the ejection method. Of course, the particleization frequency for the composition, the nozzle diameter, the number of heads, etc., in the inkjet device 140 can be modified arbitrarily according to the size, type, etc., of the subject (color filter).

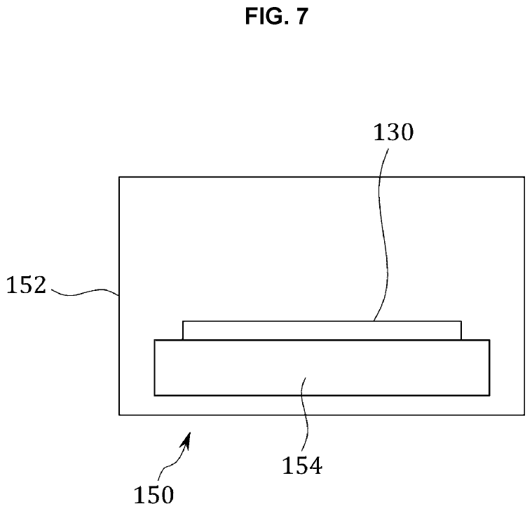

As the solution such as a color ink is ejected to the inside of the partition walls 110, the pattern 120 may be formed, where the surface of the pattern 120 may be formed in a convex shape as in FIG. 4 due to the surface tension of the solution. Here, the substrate 130 may be inserted into a chamber (see FIGS. 7 to 9) that is capable of applying pressure and performing a heat treatment simultaneously to be heated and pressurized. The convexly formed pattern 120 may be dried and hardened by the heating and, at the same time, may have its surface flattened by the pressurization as in FIG. 6.

The temperature and time of the heat treatment within the chamber can be modified according to the type of solution used, the sizes of the partition walls, the size and type of the color filter being manufactured, etc. For example, after a coloring pigment is ejected with an inkjet device 140, heating can be applied for about 1-30 minutes at a temperature of 50-250° C. Also, within the chamber, during the entirety of or a portion of the heat treatment process, the pressurization can be performed simultaneously for the pattern 120.

Referring to FIG. 5, the pressure on the pattern 120 within the chamber may cause the same forces to be applied perpendicularly on the convexly formed surface. If these forces are decomposed into vector components at the respective portions, then different forces are applied in the vertical direction at the respective portions. That is, the largest vertical force is applied at the most convex portion, and the vertical vector components gradually decrease as the distances increase in both directions therefrom. The degree of convexity or the thickness (the vertical distance h from the imaginary line a to the surface in FIG. 5) of the pattern may also gradually decrease with increased distances to the sides from the center. Consequently, since a vertical force that is proportional to or corresponding to the thickness h of the pattern is applied, the pattern 120 can be pressed, and its surface can be kept flat.

The pattern 120 formed on the inside of the partition walls 110 can be formed symmetrically about the center. Since the horizontal vector components applied on the surface of the pattern 120 are also symmetrical, these will offset each other out and have a sum of 0.

The pressure and time for the pattern 120 can be changed according to various conditions such as the type and amount of solution used, the sizes of the partition walls, the size of the color filter being manufactured, etc. Of course, the pressure inside the chamber can be made greater than the atmospheric pressure (1 bar).

With a method for pattern forming according to this embodiment, the pattern 120 formed by ejection with an inkjet device 140 can be dried and hardened via a heat treatment while the pattern is flattened by pressurization inside the chamber, so that the surface of the pattern 120 can maintain a degree of flatness even after the heat treatment is finished.

The pressurization can be performed throughout the entire heat treatment procedure inside the chamber. It is also possible to perform the heat treatment and the pressurization simultaneously after first performing only the pressurization for a certain duration of time, in which case the heat treatment can be performed after the convex pattern 120 has been flattened, and the flattening can be performed more easily.

FIGS. 7 to 9 are diagrams illustrating a pattern forming device 150, 160, 170 according to a first, second, and third disclosed embodiment of the invention, respectively.

Referring to FIG. 7, a device 150 for pattern forming according to a first disclosed embodiment may include a chamber 152 that has a sealed interior space and a hot plate 154 that serves as a heat treatment unit within the chamber 152. The substrate 130 may be placed on an upper surface of the hot plate 154. In the interior of the chamber 152, a pressure greater than or equal to atmospheric pressure can be applied by a pressurization unit (not shown), and at the same time, the temperature in the chamber 152 can be raised to a certain temperature or higher by the hot plate 154, whereby the drying and hardening of the pattern 120 can be performed.

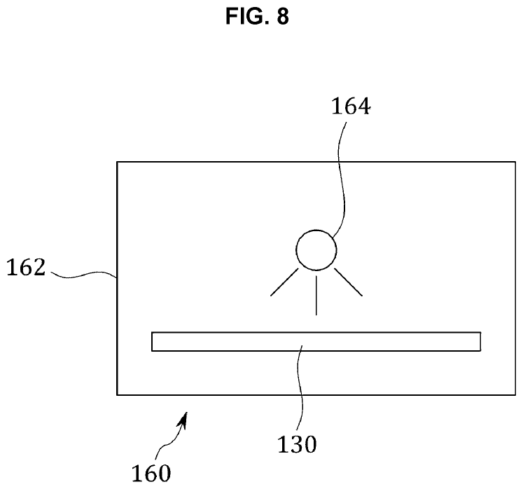

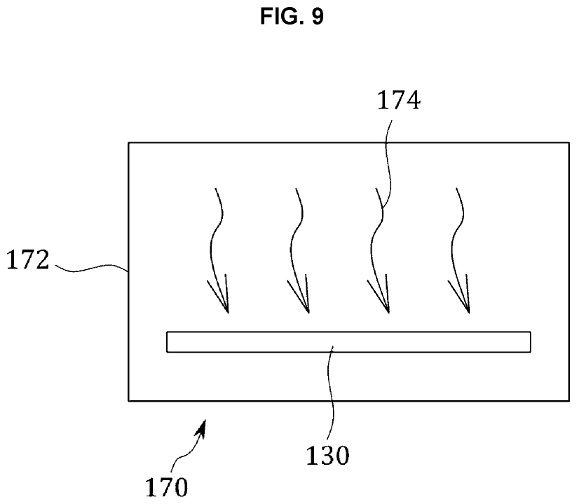

Referring to FIG. 8, a device 160 for pattern forming according to a second disclosed embodiment can have the substrate 130 inserted into a sealed chamber 162, where the heat treatment unit can correspond to an infrared lamp 164. Referring to FIG. 9, a device 170 for pattern forming according to a third disclosed embodiment can have the substrate 130 inserted into a sealed chamber 172, where the heat treatment unit can correspond to a hot air blower 174. The hot air blower 174 can be implemented as a part of the chamber 172 or a separate device (not shown).

The interior of the chamber 152, 162, 172 can be pressurized by a pressurization unit (not shown) to a pressure greater than or equal to atmospheric pressure. As such a pressurization unit is well known technology, a detailed description thereof is omitted.

A device 150, 160, 170 for pattern forming according to any of the first to third disclosed embodiments can be positioned immediately after the inkjet device 140 to be able to perform the pressurization and heat treatment immediately after the ejection of the solution 142.

Thus, as the device and method for pattern forming according to an embodiment of the invention can flatten the pattern, it is possible to provide a color filter that has excellent color reproduction and has almost no discrepancies in transmittance values. Such a flattened color filter can be applied to display devices such as organic light-emitting diode (OLED) and liquid crystal display (LCD) devices.

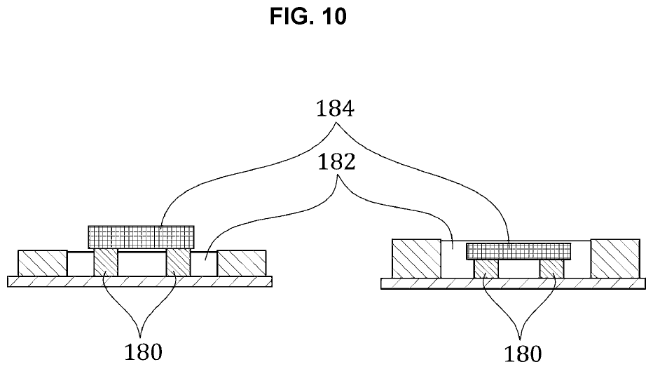

A device and method for pattern forming according to an embodiment of the invention can also be applied to a QDOLED or a QNED device using quantum dots, together with a method of evening the diffusion of light when a mini LED or micro LED device is used as a backlight or as a display itself. An embodiment can also be applied to a method of evening out the surface with inkjet printing after forming metal wiring. That is, as illustrated in FIG. 10, an embodiment can be applied to a method of forming a metal electrode 180 and then flattening out its surface using a solution 182. A mini LED or a micro LED device 184 can be mounted on the metal electrode 180.

In addition to the context of displays, a device and method for pattern forming according to an embodiment of the invention can also be used for ejecting a pattern onto a substrate for a semiconductor or various other circuits by inkjet printing and flattening the ejected pattern afterwards. Moreover, a device and method for pattern forming according to an embodiment of the invention can be applied to cases where partition walls 110 are included and cases where partition walls are not included.

While the descriptions above are provided for certain embodiments of the present invention, it should be appreciated by the person having ordinary skill in the relevant field of art that various modifications and alterations can be made to the present invention without departing from the spirit and scope of the present invention set forth in the scope of claims below.

### DESCRIPTION OF REFERENCE NUMERALS

110: partition wall

120: pattern

130: substrate

140: inkjet device

150, 160, 170: device for pattern forming

What is claimed is:

1. A method for pattern forming using inkjet printing, the method comprising:
forming a pattern by ejecting a solution by inkjet printing; and
obtaining a degree of flatness by applying a pressure greater than or equal to atmospheric pressure simultaneously with a heat treatment on the pattern,
wherein a cross section of the pattern is formed with a convex surface by the inkjet printing and is flattened by the applying of pressure as a same force is applied perpendicularly on each surface of the pattern.

2. The method for pattern forming using inkjet printing according to claim 1, further comprising:
forming partition walls on one side of a substrate,
wherein the solution is ejected to an inside of the partition walls.

3. The method for pattern forming using inkjet printing according to claim 1, wherein the pattern is a color filter for a display.

4. The method for pattern forming using inkjet printing according to claim 1, wherein the heat treatment is performed by at least one of a hot plate, a lamp, and a hot air blower and is performed to dry and harden the ejected solution.

5. A device for pattern forming using inkjet printing, the device comprising:
a chamber having a sealed interior space;
a heat treatment unit configured to apply heat treatment to a substrate positioned in the interior space; and
a pressurization unit configured to flatten a pattern formed on the substrate by applying a pressure greater than or equal to atmospheric pressure in the interior space.

6. The device for pattern forming using inkjet printing according to claim 5, wherein the heat treatment unit comprises at least one of a hot plate, a lamp, and a hot air blower.
